(19) United States
(12) Patent Application Publication
(10) Pub. No.: US 2025/0326083 A1
(43) Pub. Date: Oct. 23, 2025

(54) POLISHING PAD AND METHOD FOR MANUFACTURING POLISHED WORKPIECE

(71) Applicant: FUJIBO HOLDINGS, INC., Tokyo (JP)

(72) Inventors: Teppei TATENO, Ehime (JP); Kouki ITOYAMA, Ehime (JP); Hitoshi SEKIYA, Ehime (JP); Kenichi KOIKE, Ehime (JP); Hiroshi KURIHARA, Ehime (JP); Satsuki YAMAGUCHI, Ehime (JP); Yamato TAKAMIZAWA, Ehime (JP)

(21) Appl. No.: 18/849,928

(22) PCT Filed: Mar. 23, 2023
(86) PCT No.: PCT/JP2023/011359

§ 371 Date: Sep. 23, 2024

(30) Foreign Application Priority Data
Mar. 24, 2022 (JP) 2022-047876

(51) Int. Cl. B24B 37/24; B24B 37/20; B24B 49/12

(52) U.S. Cl. CPC B24B 37/24; B24B 37/205; B24B 49/12

(57) ABSTRACT

A polishing pad including a polishing layer, and an end point detection window that is provided in an opening of the polishing layer, wherein in a dynamic viscoelasticity measurement which is performed under conditions of a tensile mode, a frequency of 1.6 Hz, 30 to 55° C., and a submerged state, a ratio (E′p40/E′w40) of a storage elastic modulus E′p40 of the polishing layer at 40° C. to a storage elastic modulus E′w40 of the end point detection window at 40° C. is 0.70 to 3.00.

### TECHNICAL FIELD

The present invention relates to a polishing pad and a method for manufacturing a polished workpiece with the use of the polishing pad.

### BACKGROUND ART

In a semiconductor manufacturing process, chemical mechanical polishing (CMP) is used in a process of planarization after an insulation film has been formed, or of forming a metal wiring. As one of important techniques required for the chemical mechanical polishing, there is a detection of an end point of polishing, for detecting whether or not the polishing process has been completed. For example, over-polishing or under-polishing with respect to the targeted end point of polishing directly leads to product defects. Because of this, in the chemical mechanical polishing, it is necessary to strictly control a polishing amount by the detection of the end point of polishing.

The chemical mechanical polishing is a complicated process, and a polishing rate varies depending on an operating state of a polishing apparatus, a quality of consumables (slurry, polishing pad, dresser and the like), and an influence of dispersion of a state with time in the polishing process. Furthermore, in recent years, the accuracy and in-plane uniformity of a remaining film thickness which is required in the semiconductor manufacturing process have become increasingly severe. Under such circumstances, it has become more difficult to detect the end point of polishing with sufficient accuracy.

As a main method of detecting the end point of polishing, an optical end point detection method, a torque end point detection method, an eddy current end point detection method and the like are known; and in the optical end point detection method, the wafer is irradiated with light through a transparent member for a window provided on the polishing pad, the reflected light is monitored, and thereby the end point is detected.

As a polishing pad which uses such an optical end point detection method, it is disclosed to aim at providing a polishing pad that can suppress accumulation of slurry in a groove of a member for the window and enhance a detection accuracy of a polishing rate, and to use a material having a higher grinding property than a material of a main body of a pad for the surface of the member for the window, in a polishing pad that has the main body of the pad and a transparent member for the window which is integrally formed with a part of the main body of the pad, for example, in Patent Literature 1.

### CITATION LIST

### Patent Literature

Patent Literature 1
Japanese Patent Laid-Open No. 2002-001647

### SUMMARY OF INVENTION

### Technical Problem

However, when the characteristics of the polishing layer and the end point detection window are made different as in Patent Literature 1, for example, a portion of the end point detection window is polished earlier than the polishing layer to form a recess, and slurry or polishing debris tend to easily accumulate in the recess, which causes (surface defects) in some cases. In addition, when the portion of the end point detection window is polished slower than the polishing layer, the end point detection window becomes a salient as polishing progresses, and causes defects; and there is a possibility of degrading the surface quality of a polished object.

The present invention has been made in view of the above problems, and an object is to provide a polishing pad that can obtain a polished object which resists causing defects and has an excellent surface quality while having the end point detection window, and a method for manufacturing the polished workpiece with the use of the polishing pad.

### Solution to Problem

The present inventors have conducted intensive studies to solve the above problems. As a result, the present inventors have found that the above problems can be solved when the end point detection window and the viscoelasticity of the polishing layer have a predetermined relationship, and have completed the present invention.

Specifically, the present invention is as follows.

[1]

A polishing pad including: a polishing layer; and an end point detection window that is provided in an opening of the polishing layer, wherein in a dynamic viscoelasticity measurement which is performed under conditions of a tensile mode, a frequency of 1.6 Hz, 30 to 55° C., and a submerged state, a ratio (E′p40/E′w40) of a storage elastic modulus E′p40 of the polishing layer at 40° C. to a storage elastic modulus E′w40 of the end point detection window at 40° C. is 0.70 to 3.00.

[2]

The polishing pad according to [1], wherein in the dynamic viscoelasticity measurement, a ratio (E′p50/E′w50) of a storage elastic modulus E′p50 of the polishing layer at 50° C. to a storage elastic modulus E′w50 of the end point detection window at 50° C. is 0.70 to 5.00.

[3]

The polishing pad according to [1] or [2], wherein in the dynamic viscoelasticity measurement, a difference (|tan δw30−tan μp30|) between a loss coefficient tan δw30 of the end point detection window at 30° C. and a loss coefficient tan δp30 of the polishing layer at 30° C. is 0.05 to 0.30.

[4]

The polishing pad according to any one of [1] to [3], wherein in the dynamic viscoelasticity measurement, a difference (|tan δw40−tan δp40|) between a loss coefficient tan δw40 of the end point detection window at 40° C. and a loss coefficient tan δp40 of the polishing layer at 40° C. is 0.05 to 0.40.

[5]

The polishing pad according to any one of [1] to [4], wherein in the dynamic viscoelasticity measurement, a difference (|tan δw50−tan δp50|) between a loss coefficient tan δw50 of the end point detection window at 50° C. and a loss coefficient tan δp50 of the polishing layer at 50° C. is 0.05 to 0.50.

[6]

The polishing pad according to any one of [1] to [5], wherein the end point detection window includes a polyurethane resin WI, and the polyurethane resin WI contains a constituent unit that is derived from an aliphatic isocyanate.

[7]

The polishing pad according to any one of [1] to [6], wherein the polishing layer includes a polyurethane resin P, and the polyurethane resin P contains a constituent unit that is derived from an aromatic isocyanate.

[8]

The polishing pad according to any one of [1] to [7], wherein the polishing layer includes hollow fine particles that are dispersed in the polishing layer.

[9]

A method for manufacturing a polished workpiece including: a polishing step of polishing an object to be polished in the presence of a polishing slurry with the use of the polishing pad according to any one of [1] to [8] to obtain the polished workpiece; and an end point detection step of detecting an end point by an optical end point detection method during the polishing.

### Advantageous Effects of Invention

According to the present invention, it is possible to provide a polishing pad that is less likely to cause defects though having an end point detection window, and can obtain a polished object excellent in a surface quality; and a method for manufacturing a polished workpiece with the use of the polishing pad.

### BRIEF DESCRIPTION OF DRAWINGS

FIG. 1 shows a schematic perspective view of a polishing pad of the present embodiment.

FIG. 2 shows a schematic sectional view of an end point detection window portion of the polishing pad of the present embodiment.

FIG. 3 shows a schematic sectional view of another aspect of the end point detection window portion of the polishing pad of the present embodiment.

FIG. 4 shows a schematic view showing a film thickness control system that is mounted on CMP.

### DESCRIPTION OF EMBODIMENTS

Hereinafter, an embodiment of the present invention (hereinafter referred to as “the present embodiment”) will be described in detail with reference to the drawings as necessary; but the present invention is not limited to this embodiment, and can be variously modified in such a range as not to deviate from the gist thereof. In the drawings, the same elements are denoted by the same reference numerals, and duplicated descriptions will be omitted. In addition, positional relationships such as up, down, left and right shall be based on the positional relationships shown in the drawings, unless otherwise specified. Furthermore, dimensional ratios in the drawings are not necessarily limited to the ratios shown in the drawings.

### 1. Polishing Pad

The polishing pad of the present embodiment includes a polishing layer, and an end point detection window that is provided in an opening of the polishing layer, wherein in a dynamic viscoelasticity measurement which is performed under conditions of a tensile mode, a frequency of 1.6 Hz, 30 to 55° C., and a submerged state, a ratio (E′p40/E′w40) of a storage elastic modulus E′p40 of the polishing layer at 40° C. to a storage elastic modulus E′w40 of the end point detection window at 40° C. is 0.70 to 3.00.

Thereby, the polishing layer and the end point detection window have closer dynamic viscoelastic properties at the time of polishing, and accordingly, even when the end point detection window which is a different type of member has been embedded in the polishing layer, it is further suppressed that defects (surface defects) occur on the surface of the polished object. Because of this, a polished object excellent in the surface quality can be obtained.

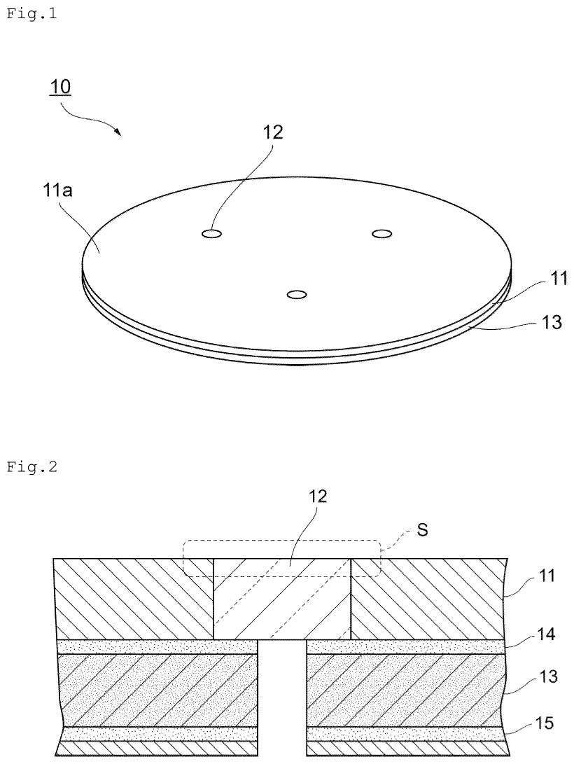

FIG. 1 shows a schematic perspective view of a polishing pad of the present embodiment. As is shown in FIG. 1, the polishing pad 10 of the present embodiment has a polishing layer 11 which is a polyurethane sheet, and an end point detection window 12; and may have a cushion layer 13 on the side opposite to a polishing surface 11a, as needed.

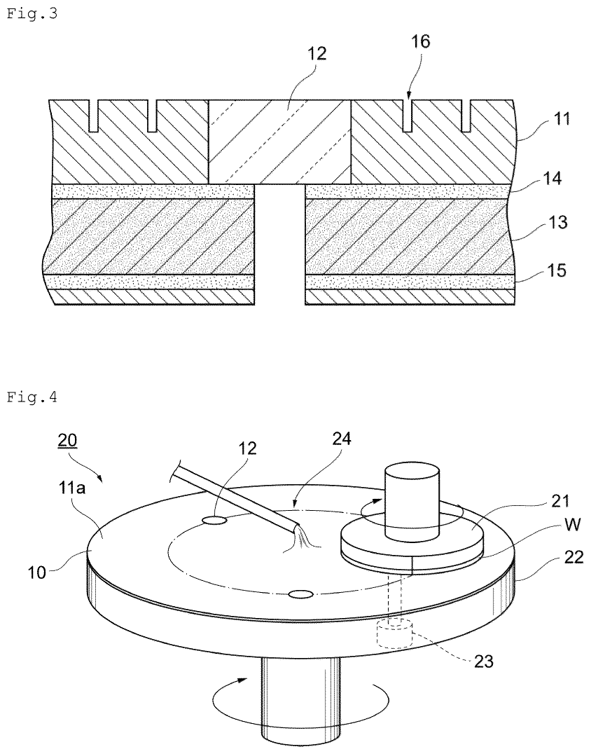

FIGS. 2 and 3 show sectional views of the periphery of the end point detection window 12 in FIG. 1. As shown in FIGS. 2 and 3, an adhesive layer 14 may be provided between the polishing layer 11 and the cushion layer 13, and on the surface of the cushion layer 13, an adhesive layer 15 for bonding to a table 22 of FIG. 4 may be provided. The polishing surface 11a of the polishing pad of the present embodiment may be flat as shown in FIG. 2, or may be an uneven shape in which grooves 16 are formed as shown in FIG. 3. The groove 16 may be formed by using a plurality of grooves having various shapes such as a concentric circle shape, a lattice shape and a radial shape, alone or in combination.

### 1. 1. End Point Detection Window

The end point detection window is a transparent member which is provided in the opening of the polyurethane sheet, and serves as a transmission path of light emitted from a film thickness detection sensor, in optical end point detection. In the present embodiment, the end point detection window is circular, but may be square, rectangular, polygonal, elliptical or the like, as needed.

In the present embodiment, the wear degrees and the like of the end point detection window and the polishing layer at the time of polishing are adjusted, and a ratio between the storage elastic moduli E's of the end point detection window and the polyurethane sheet is regulated, from the viewpoint of suppressing the occurrence of defects (surface defects) in the polished object due to excessive polishing of one of the end point detection window and the polishing layer.

### 1. 1. 1. Dynamic Viscoelasticity

The storage elastic moduli E's of the end point detection window and the polishing layer in the present embodiment can be determined by a dynamic viscoelasticity measurement which is performed under conditions of a tensile mode, a frequency of 1.6 Hz, 30 to 55° C., and a submerged state. For information, in the present embodiment, it is premised that the dynamic viscoelasticity is measured in the submerged state, unless otherwise specified.

In the polishing step in which the slurry comes in contact with the polishing pad, the polishing surface is in the submerged state. For this reason, in the present embodiment, a ratio between the dynamic viscoelasticities of the end point detection window and the polishing layer in the submerged state is regulated, at 40° C. which corresponds to the temperature at the time of polishing. More specifically, in the dynamic viscoelasticity measurement which is performed under conditions of the tensile mode, the frequency of 1.6 Hz, 30 to 55° C., and the submerged state, a ratio (E′p40/E′w40) of a storage elastic modulus E′p40 of the polishing layer at 40° C. to a storage elastic modulus E′w40 of the end point detection window at 40° C. is regulated.

The ratio (E′p40/E′w40) is 0.70 to 3.00, is preferably 0.80 to 2.50, and is more preferably 0.90 to 2.00. When the ratio (E′p40/E′w40) is within the above range, the characteristics of the end point detection window and the polishing layer at the time of polishing become similar, and accordingly, the surface quality of the obtained polished object is further enhanced. Thereby, a contact state with the object to be polished (workpiece) at the time of polishing is further improved, obstinate pressing by polishing debris is also suppressed, and the occurrence of scratches is suppressed.

In the dynamic viscoelasticity measurement in the above submerged state, it is preferable for a ratio (E′p50/E′w50) of a storage elastic modulus E′p50 of the polishing layer at 50° C. to a storage elastic modulus E′w50 of the end point detection window at 50° C. to be 0.70 to 5.00, is more preferable to be 0.80 to 4.00, and is further preferable to be 0.90 to 3.00. When the ratio (E′p50/E′w50) is within the above range, the characteristics of the end point detection window and the polishing layer at the time of polishing become similar, and accordingly, the surface quality of the obtained polished object tends to be further enhanced.

In the dynamic viscoelasticity measurement in the above submerged state, it is preferable for a difference (|tan δw30−tan δp30|) between a loss coefficient tan δw30 of the end point detection window at 30° C. and a loss coefficient tan δp30 of the polishing layer at 30° C. to be 0 to 0.30, is more preferable to be 0.05 to 0.30, and is further preferable to be 0.05 to 0.20.

In the dynamic viscoelasticity measurement in the above submerged state, it is preferable for a difference (|tan δw40−tan δp40|) between a loss coefficient tan δw40 of the end point detection window at 40° C. and a loss coefficient tan δp40 of the polishing layer at 40° C. to be 0 to 0.40, is more preferable to be 0.05 to 0.40, and is further preferable to be 0.05 to 0.30.

In the dynamic viscoelasticity measurement in the above submerged state, it is preferable for a difference (|tan δw50−tan δp50|) between a loss coefficient tan δw50 of the end point detection window at 50° C. and a loss coefficient tan δp50 of the polishing layer at 50° C. to be 0 to 0.50, is more preferable to be 0.05 to 0.50, and is further preferable to be 0.05 to 0.40.

When the difference (|tan δw30−tan δp30|), the difference (|tan δw40−tan δp40|) and the difference (|tan δw50−tan δp50|) are within the above ranges, respectively, the characteristics of the end point detection window and the polishing layer at the time of polishing become similar, and accordingly, the surface quality of the obtained polished object tends to be further enhanced.

It is preferable for a storage elastic modulus E′w40 of the end point detection window in the submerged state at 40° C. to be 6.0 to 50×10⁷ Pa, is more preferable to be 8.0 to 40×10⁷ Pa, and is further preferable to be 10 to 30×10⁷ Pa.

It is preferable for a storage elastic modulus E′w50 of the end point detection window in the submerged state at 50° C. to be 2.0 to 40×10⁷ Pa, is more preferable to be 3.0 to 30×10⁷ Pa, and is further preferable to be 4.0 to 20×10⁷ Pa.

It is preferable for the tan δw40 of the end point detection window in the submerged state at 40° C. to be 0.1 to 0.7, is more preferable to be 0.1 to 0.6, and is further preferable to be 0.1 to 0.5.

It is preferable for the tan δw50 of the end point detection window in the submerged state at 50° C. to be 0.1 to 0.6, is more preferable to be 0.1 to 0.5, and is further preferable to be 0.1 to 0.4.

When the E′w40, the E′w50, the tan δw40, and the tan δw50 are within the above ranges, respectively, the characteristics of the end point detection window and the polishing layer at the time of polishing become similar, and accordingly, the surface quality of the obtained polished object tends to be further enhanced.

The measurement conditions of the dynamic viscoelasticity measurement are not particularly limited, and the measurement can be performed under the conditions described in Examples.

### 1. 1. 3. Constituent Material

A material constituting the end point detection window is not particularly limited as long as the material is a transparent member which can function as a window, and examples thereof include a polyurethane resin WI, a polyvinyl chloride resin, a polyvinylidene fluoride resin, a polyether sulfone resin, a polystyrene resin, a polyethylene resin, and a polytetrafluoroethylene resin. Among the resins, the polyurethane resin WI is preferable. By using such a resin, it is possible to more easily adjust the above dynamic viscoelastic properties and transparency, and more enhance the surface quality.

The polyurethane resin WI can be synthesized from a polyisocyanate and a polyol, and contains a constituent unit derived from the polyisocyanate and a constituent unit derived from the polyol.

1. 1. 3. 1. Constituent Unit Derived from Polyisocyanate

The constituent unit derived from the polyisocyanate is not particularly limited, and examples thereof include a constituent unit derived from an alicyclic isocyanate, a constituent unit derived from an aliphatic isocyanate, and a constituent unit derived from an aromatic isocyanate. Among the constituent units, it is preferable for the polyurethane resin WI to contain a constituent unit derived from the alicyclic isocyanate and/or the aliphatic isocyanate, and is more preferable to contain a constituent unit derived from the aliphatic isocyanate. Thereby, it becomes easy to adjust the dynamic viscoelastic properties to the above range; and the transparency tends to be further enhanced, and in addition, the surface quality tends to be further enhanced.

The alicyclic isocyanate is not particularly limited, and examples thereof include 4,4′-methylene-bis (cyclohexyl isocyanate) (hydrogenated MDI), cyclohexylene-1,2-diisocyanate, cyclohexylene-1,4-diisocyanate, and isophorone diisocyanate.

The aliphatic isocyanate is not particularly limited, and examples thereof include hexamethylene diisocyanate (HDI), pentamethylene diisocyanate (PDI), tetramethylene diisocyanate, propylene-1,2-diisocyanate, butylene-1,2-diisocyanate, trimethylene diisocyanate, and trimethyl hexamethylene diisocyanate.

The aromatic isocyanate is not particularly limited, and examples thereof include phenylene diisocyanate, 2,6-tolylene diisocyanate (2,6-TDI), 2,4-tolylene diisocyanate (2,4-TDI), xylylene diisocyanate, naphthalene diisocyanate, and diphenylmethane-4,4′-diisocyanate (MDI).

1. 1. 3. 2. Constituent Units Derived from Polyol

The constituent unit derived from a polyol is not particularly limited, and examples thereof include a low molecular weight polyol having a molecular weight of less than 300, and a high molecular weight polyol having a molecular weight of 300 or more.

The low molecular weight polyol is not particularly limited, and examples thereof include: low molecular weight polyols each having two hydroxyl groups, such as ethylene glycol, propylene glycol, diethylene glycol, triethylene glycol, 1,2-butylene glycol, 1,3-butylene glycol, 2,3-butylene glycol, 1,4-butylene glycol, 1,5-pentanediol, neopentyl glycol, 1,6-hexane glycol, 2,5-hexane diol, dipropylene glycol, 2,2,4-trimethyl-1,3-pentane diol, tricyclodecane dimethanol and 1,4-cyclohexane dimethanol; and low molecular weight polyols having three or more hydroxyl groups, such as glycerin, hexanetriol, trimethylolpropane, isocyanuric acid, and erythritol. The low molecular weight polyols may be used alone or in combination of two or more types thereof.

Among the low molecular weight polyols, the low molecular weight polyols having three or more hydroxyl groups are preferable, and glycerin is more preferable. By using such a low molecular weight polyol, it becomes easy to adjust the dynamic viscoelastic properties to the above range, and it becomes possible to adjust an abrasion loss; and the transparency tends to be further enhanced, and in addition, the surface quality tends to be further enhanced.

It is preferable for a content of the constituent unit derived from the low molecular weight polyol having three or more hydroxyl groups to be 7.5 to 30 parts by mass with respect to 100 parts by mass of the constituent unit derived from the polyisocyanate, is more preferable to be 10 to 25 parts by mass, and is further preferable to be 12.5 to 20 parts by mass. When the content of the constituent unit derived from the low molecular weight polyol having three or more hydroxyl groups is within the above range, it becomes easy to adjust the dynamic viscoelastic properties to the above range; and the transparency tends to be further enhanced, and the surface quality tends to be further enhanced.

In addition, the high molecular weight polyol is not particularly limited, and examples thereof include polyether polyol, polyester polyol, polycarbonate polyol, polyether polycarbonate polyol, polyurethane polyol, epoxy polyol, vegetable oil polyol, polyolefin polyol, acrylic polyol, and vinyl monomer-modified polyol. The high molecular weight polyols may be used alone or in combination of two or more types thereof.

For information, it is preferable for a number average molecular weight of the high molecular weight polyol to be 300 to 3000, and is more preferable to be 500 to 2500. By using such a high molecular weight polyol, it tends to become easy to adjust the dynamic viscoelastic properties to the above range.

Among the high molecular weight polyols, the polyether polyol is preferable, and poly(oxytetramethylene) glycol is more preferable. By using such a high molecular weight polyol, it becomes easy to adjust the dynamic viscoelastic properties to the above range. In addition, the transparency tends to be further enhanced, and yellowing resistance of the window tends to be further enhanced.

It is preferable for a content of the constituent unit derived from the polyether polyol to be 60 to 130 parts by mass with respect to 100 parts of the constituent unit derived from the polyisocyanate, is preferable to be 65 to 120 parts by mass, and is more preferable to be 70 to 110 parts by mass. When the content of the constituent unit derived from the polyether polyol is within the above range, it becomes easy to adjust the dynamic viscoelastic properties to the above range; and the transparency tends to be further enhanced, and in addition, the yellowing resistance of the window tends to be further enhanced.

As the polyol, it is preferable to use a low molecular weight polyol and a high molecular weight polyol in combination, and is more preferable to use a low molecular weight polyol having three or more hydroxyl groups and a polyether polyol in combination. Thereby, it becomes easy to adjust the dynamic viscoelastic properties to the above range; and the transparency tends to be further enhanced, and in addition, the yellowing resistance of the window tends to be further enhanced.

From the viewpoint of the above, it is preferable for a content of the polyether polyol to be 2.0 to 15.0 parts with respect to 1 part of the low molecular weight polyol having three or more hydroxyl groups, is more preferable to be 3.0 to 12.5 parts, and is further preferable to be 4.0 to 9.0 parts.

### 1. 2. Polishing Layer

The polishing layer of the present embodiment has an opening in which the end point detection window is embedded. The position of the opening is not particularly limited, but it is preferable to provide the opening at a position in a radial direction corresponding to a film thickness detection sensor 23 installed on the table 22. In addition, the number of openings is not particularly limited, but it is preferable to provide a plurality of openings at positions in the same radial direction so that the window passes above the film thickness detection sensor 23 a plurality of times while the polishing pad 10 attached to the table 22 makes one rotation.

The form of the polishing layer is not particularly limited, and examples thereof include a foamed molded body of a resin, a non-foamed molded body, and a resin-impregnated base material in which a resin is impregnated in a fiber base material.

Here, the foamed molded body of a resin refers to a foamed body which does not have a fiber base material and is composed of a predetermined resin. The foamed shape is not particularly limited, and examples thereof include a spherical bubble, a substantially spherical bubble, a teardrop-shaped bubble, and continuous bubbles in which the individual bubbles are partially connected to each other.

In addition, the non-foamed molded body of the resin refers to a non-foamed body which does not have a fiber base material and is composed of a predetermined resin. The non-foamed body means a body having no bubbles as described above. In the first embodiment, the non-foamed molded body of a resin also includes a product in which a curable composition is attached onto a substrate such as a film and is cured. The non-foamed molded body of a resin also includes a resin cured product, more specifically, which is formed by a gravure coater method, a small-diameter gravure coater method, a reverse roll coater method, a transfer roll coater method, a kiss coater method, a die coater method, a screen printing method, a spray coating method, or the like.

Furthermore, the resin-impregnated base material refers to a product in which a resin is impregnated in a fiber base material. Here, the fiber base material is not particularly limited, and examples thereof include woven fabrics, nonwoven fabrics, and knitted fabrics.

### 1. 2. 1. Dynamic Viscoelasticity

It is preferable for a storage elastic modulus E′p40 of the polishing layer in the submerged state at 40° C. to be 10 to 40×10⁷ Pa, is more preferable to be 15 to 35×10⁷ Pa, and is further preferable to be 20 to 30×10⁷ Pa.

It is preferable for a storage elastic modulus E′p50 of the polishing layer in the submerged state at 50° C. to be 50 to 35×10⁷ Pa, is more preferable to be 10 to 30×10⁷ Pa, and is further preferable to be 15 to 25×10⁷ Pa.

It is preferable for the tan δp40 of the polishing layer in the submerged state at 40° C. to be 0.01 to 0.25, is more preferable to be 0.03 to 0.20, and is further preferable to be 0.05 to 0.15.

It is preferable for the tan δp50 of the polishing layer in the submerged state at 50° C. to be 0.01 to 0.25, is more preferable to be 0.03 to 0.20, and is further preferable to be 0.05 to 0.15.

When the E′ p40, the E′p50, the tan δ040 and the tan δ050 are within the above ranges, respectively, the characteristics of the end point detection window and the polishing layer at the time of polishing become similar, and accordingly, the surface quality of the obtained polished object tends to be further enhanced.

### 1. 2. 2. Polyurethane Sheet

In the following, a polyurethane sheet will be given as one example of the polishing layer. The polyurethane resin P which constitutes the polyurethane sheet is not particularly limited, and examples of the polyurethane resin include a polyester-based polyurethane resin, a polyether-based polyurethane resin, and a polycarbonate-based polyurethane resin. These resins may be used alone or in combination of two or more types thereof.

Such a polyurethane resin P can be synthesized from a polyisocyanate and a polyol, and in particular, a reaction product of a urethane prepolymer and a curing agent is preferable. Here, the urethane prepolymer can be synthesized from a polyisocyanate and a polyol. The polyisocyanate, the polyol and the curing agent which constitute the polyurethane resin P will be described below.

1. 2. 2. 1. Constituent Unit Derived from Polyisocyanate

The constituent unit derived from the polyisocyanate is not particularly limited, and examples thereof include a constituent unit derived from an alicyclic isocyanate, a constituent unit derived from an aliphatic isocyanate, and a constituent unit derived from an aromatic isocyanate. Among the constituent units, aromatic isocyanates are preferable, and 2,4-tolylene diisocyanate (2,4-TDI) is more preferable.

Examples of the alicyclic isocyanate, the aliphatic isocyanate and the aromatic isocyanate include the same ones as those exemplified in the above end point detection window.

1. 2. 2. 2. Constituent Units Derived from Polyol

The constituent unit derived from a polyol is not particularly limited, and examples thereof include a low molecular weight polyol having a molecular weight of less than 300, and a high molecular weight polyol having a molecular weight of 300 or more. Among the constituent units, it is preferable to use at least a low molecular weight polyol, and is preferable to use a low molecular weight polyol and a high molecular weight polyol in combination.

Examples of the low molecular weight polyol and the high molecular weight polyol include the same ones as those exemplified in the above end point detection window. Among the polyols, as the low molecular weight polyol, a low molecular weight polyol having two hydroxyl groups is preferable, and diethylene glycol is more preferable. In addition, the high molecular weight polyol is preferably a polyether polyol, and is more preferably poly(oxytetramethylene) glycol.

### 1. 2. 2. 3. Curing Agent

The curing agent is not particularly limited, and examples thereof include polyamine and polyol. The curing agents may be used alone or in combination of two or more types thereof.

The polyamine is not particularly limited, but examples thereof include: aliphatic polyamines such as ethylenediamine, propylene diamine, and hexamethylenediamine; alicyclic polyamines such as isophorone diamine and dicyclohexylmethane-4,4′-diamine; and aromatic polyamines such as 3,3′-dichloro-4,4′diaminodiphenyl methane (MOCA), 4-methyl-2,6-bis(methylthio)-1,3-benzenediamine, 2-methyl-4,6-bis(methylthio)-1,3-benzenediamine, and 2,2-bis(3-amino-4-hydroxyphenyl) propane.

Among the polyamines, aromatic polyamines are preferable, and 3′-dichloro-4,4′-diaminodiphenyl methane (MOCA) is more preferably used.

Examples of the polyol include the same polyols as those exemplified in the above end point detection window. Among the polyols, high molecular weight polyols are preferable, polyether polyol is more preferable, and polypropylene glycol is further preferable.

### 1. 2. 2. 4. Hollow Fine Particle

It is preferable that the above polishing layer contains hollow fine particles which are dispersed in the polishing layer. Specifically, it is preferable that the above polyurethane sheet is a foamed polyurethane sheet containing a polyurethane resin P and hollow fine particles which are dispersed in the polyurethane resin P. Because such a polyurethane sheet becomes a sheet which has closed bubbles derived from the hollow fine particles, the above dynamic viscoelastic properties tend to be easily adjusted within the above range.

As the hollow fine particles, commercially available hollow fine particles may be used, or hollow fine particles which have been obtained by synthesis according to a common method may be used. The material of the outer shell of the hollow fine particle is not particularly limited, and examples thereof include polyvinyl alcohol, polyvinyl pyrrolidone, poly(meth)acrylic acid, polyacrylamide, polyethylene glycol, polyhydroxyether acrylite, maleic acid copolymer, polyethylene oxide, polyurethane, acrylonitrile-vinylidene chloride copolymer, acrylonitrile-methyl methacrylate copolymer, and vinyl chloride-ethylene copolymer.

The shape of the hollow fine particle is not particularly limited, and may be, for example, spherical or substantially spherical. In addition, when the hollow fine particle is an expandable balloon, the hollow fine particle may be used in an unexpanded state or may be used in an expanded state.

It is preferable for an average particle diameter of the hollow fine particles contained in the polyurethane sheet to be 5 to 200 μm, is more preferable to be 5 to 80 μm, is further preferable to be 5 to 50 μm, and is particularly preferable to be 5 to 35 μm. When the average particle diameter is within the above range, the dynamic viscoelastic properties tend to be easily adjusted within the above range. For information, the average particle diameter can be measured by a laser diffraction particle size distribution measuring apparatus (for example, Mastersizer 2000 manufactured by Spectris Co., Ltd.) or the like.

### 1. 3. Others

The polishing pad of the present embodiment may have a cushion layer on the side opposite to the polishing surface of the polishing layer, and may have an adhesive layer between the polishing layer and the cushion layer, or on the surface of the cushion layer which is not on the polishing layer side (the surface to be bonded to a polishing machine). In this case, the cushion layer and the adhesive layer shall have openings at the same positions as positions at which the end point detection windows of the polishing layer are positioned.

### 2. Method for Manufacturing Polishing Pad

A method for manufacturing the polishing pad of the present embodiment is not particularly limited, but includes a step of obtaining a resin block in which a member for the window is embedded, for example, by filling a resin composition constituting the polishing layer into a mold to which the member for the window serving as an end point detection window is fixed, and curing the resin composition, and a step of obtaining a polyurethane sheet having the end point detection window in the opening thereof, by slicing the obtained resin block; and may subject the polishing surface of the obtained polyurethane sheet to dressing treatment, as needed.

For information, a temperature at the time of slicing is preferably 70 to 100° C. In addition, a temperature in the dressing treatment is preferably 20 to 30° C.

### 3. Method for Manufacturing Polished Workpiece

The method for manufacturing a polished workpiece of the present embodiment includes: a polishing step of polishing an object to be polished with the use of the above polishing pad in the presence of a polishing slurry to obtain the polished workpiece; and an end point detection step of detecting an end point by an optical end point detection method during the polishing.

### 3.1. Polishing Step

The polishing step may be primary lapping polishing (rough lapping), secondary lapping (finish lapping), primary polishing (rough polishing), secondary polishing (finish polishing), or a combination of these polishing processes. For information, “lapping” here means polishing at a relatively high rate with the use of coarse abrasive grains, and “polishing” means polishing at a relatively low rate with the use of fine abrasive grains for enhancing the surface quality.

In the polishing processes, it is preferable that the polishing pad of the present embodiment is used for chemical mechanical polishing (CMP). Hereinafter, a method for manufacturing a polished article of the present embodiment will be described by taking the chemical mechanical polishing as an example, but the method for manufacturing the polished article of the present embodiment is not limited to the following.

The object to be polished is not particularly limited, and examples thereof include materials for semiconductor devices, electronic components and the like; and particularly include thin substrates (object to be polished) such as Si substrates (silicon wafers), SiC (silicon carbide) substrates, GaAs (gallium arsenide) substrates, glass, substrates for a hard disk or an LCD (liquid crystal display). In particular, the examples include a semiconductor device having a metal wiring of W (tungsten), Cu (copper) or the like.

The polishing method is not particularly limited, and can employ a conventionally known method. The method includes, for example, firstly pressing the object to be polished that has been held by a holding surface plate which has been arranged so as to face the polishing pad, against a polishing surface side, and rotating the polishing pad and/or the holding surface plate, while supplying a slurry from an outside. The polishing pad and the holding surface plate may rotate in the same direction at different rotational speeds, or may rotate in different directions. In addition, the object to be polished may be polished while moving (rotating) inside a frame portion, during the polishing process.

The slurry may include: water; chemical components such as an oxidizing agent represented by hydrogen peroxide; additives; and abrasive grains (polishing particles; for example, SiC, SiO₂, Al₂O₃ and CeO₂), depending on the object to be polished, polishing conditions and the like.

### 3.2. End Point Detection Step

The method for manufacturing a polished workpiece of the present embodiment includes an end point detection step of detecting the end point by an optical end point detection method, in the above polishing step. As the end point detection method by the optical end point detection method, specifically, a conventionally known method can be used.

FIG. 4 shows a schematic view of the end point detection method by the optical end point detection method. This schematic view shows a chemical mechanical polishing process of pressing a wafer W held by a top ring 21 against the polishing pad 10 attached to the table 22 while the slurry 24 is allowed to flow, and thereby polishing and planarizing an uneven film on the surface of the wafer W. In the polishing apparatus 20, the film thickness detection sensor 23 for monitoring the film thickness is mounted in the table 22, so as to detect the planarization and simultaneously the end point of a predetermined film thickness, and accurately end the process. The film thickness detection sensor 23, for example, irradiates a polished surface of the wafer W with light, and measures and analyzes the spectral intensity characteristics of the reflected light; and thereby, can detect the end point of polishing.

More specifically, the film thickness detection sensor 23 emits light to the surface of the wafer W through the end point detection window 12, and detects the strength and weakness of the reflection intensity, which is caused by a phase difference between the light reflected by the film on the wafer W (wafer surface) and the light reflected at the interface between the film on the wafer W and the substrate of the wafer; and thereby, can detect a change of the film thickness.

### EXAMPLES

The present invention will be described in more detail below with reference to Examples and Comparative Examples. The present invention is not limited in any way by the following Examples. Note that the term “parts” shall mean parts by mass.

### Production Example 1: End Point Detection Window 1

A transparent member to become the end point detection window 1 was obtained by a reaction of 100 parts of 4,4′ methylenebis(cyclohexyl isocyanate), 90.6 parts of poly(oxytetramethylene) glycol (PTMG) having a number average molecular weight of 1000, and 16.7 parts of glycerin.

### Production Example 2: End Point Detection Window 2

A transparent member to become the end point detection window 2 was obtained by a reaction of 100 parts of 4,4′ methylenebis(cyclohexyl isocyanate), 103.6 parts of poly(oxytetramethylene) glycol (PTMG) having a number average molecular weight of 1000, and 15.9 parts of glycerin.

### Production Example 3: End Point Detection Window 3

A transparent member to become the end point detection window 3 was obtained by a reaction of 100 parts of 4,4′ methylenebis(cyclohexyl isocyanate), 78.6 parts of poly(oxytetramethylene) glycol (PTMG) having a number average molecular weight of 650, 4.5 parts of glycerin, and 10.5 parts of ethylene glycol.

### Example 1

A urethane prepolymer mixed liquid was obtained by adding and mixing 100 parts of a urethane prepolymer which had an NCO equivalent of 420 and was obtained by a reaction of 2,4-tolylene diisocyanate (2,4-TDI), poly(oxytetramethylene) glycol (PTMG) having a number average molecular weight of 650, poly(oxytetramethylene) glycol (PTMG) having a number average molecular weight of 1000, and diethylene glycol (DEG), with 2.9 parts of unexpanded hollow fine particles (average particle diameter: 8.5 μm) having a shell portion composed of acrylonitrile-vinylidene chloride copolymer. An obtained urethane prepolymer mixed liquid was charged into a first liquid tank and was kept at 60° C. In addition, separately from the first liquid tank, 28.0 parts of 3,3′-dichloro-4,4′-diaminodiphenyl methane (methylenebis-o-chloroaniline) (MOCA) was charged into a second liquid tank as a curing agent, was heated and melted at 120° C., and was mixed; and further defoamed under reduced pressure. Thus, a curing agent melt was obtained.

Next, the liquids in the first liquid tank and the second liquid tank were injected from respective injection ports of a mixer having two injection ports, and were mixed by stirring; and a mixed liquid was obtained.

Then, the obtained mixed liquid was cast in a formwork in which the end point detection window 1 obtained as described above was previously installed, and was primarily cured at 80° C. for 30 minutes. The formed block-shaped molded product was taken out from the formwork, and was secondarily cured in an oven at 120° C. for 4 hours; and a urethane resin block was obtained. The obtained urethane resin block was left to cool to 25° C.

After that, the resultant block was heated again in an oven at 120° C. for 5 hours, and then was subjected to slicing treatment; the sliced surface was subjected to grinding (buffing) treatment as needed; and a foamed polyurethane sheet was obtained. A double-sided tape was attached to the back surface of the obtained polyurethane sheet, a cushion layer was laminated therewith, and a double-sided tape was further attached to the surface of the cushion layer; and thereby a polishing pad was obtained.

### Example 2

A polishing pad of Example 2 was obtained by the same operation as in Example 1, except that the end point detection window 2 produced in the above Production Example 2 was used in place of the end point detection window 1.

### Comparative Example 1

A polishing pad of Comparative Example 1 was obtained by the same operation as in Example 1, except that the end point detection window 3 produced in the above Production Example 3 was used in place of the end point detection window 1.

### [Dynamic Viscoelasticity Measurement]

The dynamic viscoelasticity of the polyurethane sheet was measured under the following conditions. Firstly, the polyurethane sheet was immersed in water at a temperature of 23° C. for 3 days. The obtained polyurethane sheet was used as a sample, and dynamic viscoelasticity was measured in water (submerged state). For information, the sample size of the end point detection window was set to be 5 cm long×0.5 cm wide×0.13 cm thick, and the sample size of the polishing layer was set to be 5 cm long×0.5 cm wide×0.13 cm thick.

### (Measurement Conditions)

Measuring apparatus: RSA G2 (manufactured by TA Instruments Japan Inc.)
Test length: 1 cm
Pretreatment of sample: kept in water at a temperature of 23° C. for 3 days
Test mode: tensile
Frequency: 1.6 Hz
Temperature range: 30 to 55° C.
Temperature rising rate: 0.3° C./min
Strain range: 0.10%
Initial load: 300 g
Measurement interval: 200 points/° C.

### [Surface Quality Confirmation Test]

The polishing pad was arranged at a predetermined position of the polishing apparatus via a double-sided tape having an acrylic adhesive agent, and polished a Cu film substrate under the following conditions.

### (Polishing Conditions)

Polishing machine: F-REX300X (manufactured by Ebara Corporation)
Disk: A188 (manufactured by 3M Japan Limited)
Number of rotations: (surface plate) 85 rpm, and (top ring) 86 rpm
Polishing pressure: 3.5 psi
Temperature of abrasive: 20° C.
Abrasive discharge amount: 200 ml/min
Abrasive: CSL 9044C (manufactured by Fujimi Incorporated) (A mixed liquid was used in which a weight ratio of a stock solution of CSL 9044C: pure water was 1:9.)
Object to be polished: Cu film substrate
Polishing time: 60 seconds
Pad break: 35 N, 10 minutes
Conditioning: Ex-situ, 35 N, 4 scans

The polished objects from the 10th sheet to the 50th sheet after having been subjected to the above polishing process were detected and evaluated for a defect (surface defect) having a size of a 155 nm or larger, with the use of a high-sensitivity measurement mode of a surface-inspecting apparatus (manufactured by KLA Corporation, Surfscan SP2XP). The surface quality was evaluated on the basis of the confirmation result of the defect (surface defect).

TABLE 1

| | | Example 1 | | Example 2 | | Comparative Example 1 | |
|---|---|---|---|---|---|---|---|
| | | E′ | | E′ | | E′ | |
| | | [×10⁷ Pa] | tan δ | [×10⁷ Pa] | tan δ | [×10⁷ Pa] | tan δ |
| End point | 30° C. | 41.0 | 0.16 | 25.6 | 0.20 | 23.8 | 0.43 |
| detection | 40° C. | 26.9 | 0.21 | 15.7 | 0.26 | 5.2 | 0.76 |
| window | 50° C. | 17.1 | 0.26 | 9.1 | 0.31 | 1.3 | 0.66 |
| | | E′ | | E′ | | E′ | |
| | | [×10⁷ Pa] | tan δ | [×10⁷ Pa] | tan δ | [×10⁷ Pa] | tan δ |
| Polishing | 30° C. | 32.1 | 0.09 | 32.1 | 0.09 | 32.1 | 0.09 |
| layer | 40° C. | 25.5 | 0.10 | 25.5 | 0.10 | 25.5 | 0.10 |
| | 50° C. | 19.7 | 0.13 | 19.7 | 0.13 | 19.7 | 0.13 |
| | | E′ | tan δ | E′ | tan δ | E′ | tan δ |
| Ratio | 30° C. | 0.78 | 0.55 | 1.25 | 0.43 | 1.35 | 0.21 |
| p/w | 40° C. | 0.95 | 0.49 | 1.62 | 0.40 | 4.90 | 0.14 |
| | 50° C. | 1.15 | 0.49 | 2.16 | 0.41 | 15.15 | 0.19 |
| | | E′ | tan δ | E′ | tan δ | E′ | tan δ |
| Difference | 30° C. | | 0.07 | | 0.12 | | 0.34 |
| \|p − w\| | 40° C. | | 0.11 | | 0.16 | | 0.66 |
| | 50° C. | | 0.13 | | 0.18 | | 0.54 |

| | | | |
|---|---|---|---|
| Scratch | ∘ | ∘ | x |

For information, the “ratio p/w” in the table indicates a ratio of the storage elastic modulus E′p of the polishing layer to the storage elastic modulus E′w of the end point detection window, or a ratio of the tan δp of the polishing layer to the tan δw of the end point detection window, each at the same temperature. For example, according to Table 1, the ratio (E′p40/E′w40) of Example 1 is 0.95, the ratio (E′p40/E′w40) of Example 2 is 1.62, and the ratio (E′p40/E′w40) of Comparative Example 1 is 4.90.

In addition, the “difference |p−w|” in the table indicates a difference between the storage elastic modulus E′w of the end point detection window and the storage elastic modulus E′p of the polishing layer, or a difference between the tan δw of the end point detection window and the tan δp of the polishing layer, each at the same temperature. For example, according to Table 1, the difference (|tan δw30−tan δp30|) of Example 1 is 0.07, the difference (|tan δw30−tan δp30|) of Example 2 is 0.12, and the difference (|tan δw30−tan δp30|) of Comparative Example 1 is 0.34.

### INDUSTRIAL APPLICABILITY

The polishing pad of the present invention has industrial applicability as a pad which is suitably used for polishing a semiconductor wafer or the like.

### REFERENCE SIGNS LIST

10 . . . polishing pad, 11 . . . polishing layer, 11a . . . polishing surface, 12 . . . end point detection window, 13 . . . cushion layer, 14, 15 . . . adhesive layer, 16 . . . groove, 20 . . . polishing apparatus, 21 . . . top ring, 22 . . . table, 23 . . . film thickness detection sensor, 24 . . . slurry, and W . . . wafer

1. A polishing pad comprising a polishing layer, and an end point detection window that is provided in an opening of the polishing layer, wherein
in a dynamic viscoelasticity measurement which is performed under conditions of a tensile mode, a frequency of 1.6 Hz, 30 to 55° C., and a submerged state, a ratio (E′p40/E′w40) of a storage elastic modulus E′p40 of the polishing layer at 40° C. to a storage elastic modulus E′w40 of the end point detection window at 40° C. is 0.70 to 3.00.

2. The polishing pad according to claim 1, wherein
in the dynamic viscoelasticity measurement, a ratio (E′p50/E′w50) of a storage elastic modulus E′p50 of the polishing layer at 50° C. to a storage elastic modulus E′w50 of the end point detection window at 50° C. is 0.70 to 5.00.

3. The polishing pad according to claim 1, wherein
in the dynamic viscoelasticity measurement, a difference (|tan δw30−tan δp30|) between a loss coefficient tan δw30 of the end point detection window at 30° C. and a loss coefficient tan δp30 of the polishing layer at 30° C. is 0.05 to 0.30.

4. The polishing pad according to claim 1, wherein
in the dynamic viscoelasticity measurement, a difference (|tan δw40−tan δp40|) between a loss coefficient tan δw40 of the end point detection window at 40° C. and a loss coefficient tan δp40 of the polishing layer at 40° C. is 0.05 to 0.40.

5. The polishing pad according to claim 1, wherein
in the dynamic viscoelasticity measurement, a difference (|tan δw50−tan δp50|) between a loss coefficient tan δw50 of the end point detection window at 50° C. and a loss coefficient tan δp50 of the polishing layer at 50° C. is 0.05 to 0.50.

6. The polishing pad according to claim 1, wherein
the end point detection window comprises a polyurethane resin WI, and
the polyurethane resin WI contains a constituent unit that is derived from an aliphatic isocyanate.

7. The polishing pad according to claim 1, wherein
the polishing layer comprises a polyurethane resin P, and
the polyurethane resin P contains a constituent unit that is derived from an aromatic isocyanate.

8. The polishing pad according to claim 1, wherein
the polishing layer comprises hollow fine particles that are dispersed in the polishing layer.

9. A method for manufacturing a polished workpiece, comprising:
a polishing step of polishing an object to be polished in the presence of a polishing slurry with the use of the polishing pad according to claim 1 to obtain the polished workpiece; and
an end point detection step of detecting an end point by an optical end point detection method during the polishing.
